(19) United States
(12) Patent Application Publication
(10) Pub. No.: US 2016/0069965 A1
(43) Pub. Date: Mar. 10, 2016

(54) SYSTEMS AND METHODS FOR TESTING BATTERY TAB ELECTRICAL CONNECTION QUALITY

(71) Applicant: GM GLOBAL TECHNOLOGY OPERATIONS LLC, Detroit, MI (US)

(72) Inventors: JASON A. LUPIENSKI, BIRMINGHAM, MI (US); LEONID C. LEV, WEST BLOOMFIELD, MI (US); ROBERT W. CHALFANT, BERKLEY, MI (US); GARRY L. VOYTOVICH, METAMORA, MI (US); NIKOLAY KONDRATYEV, WEST BLOOMFIELD, MI (US)

(21) Appl. No.: 14/477,528

(22) Filed: Sep. 4, 2014

(51) Int. Cl. G01R 31/36

(52) U.S. Cl. CPC G01R 31/3696; G01R 31/3658; G01R 31/3662

(57) ABSTRACT

Systems and methods for determining the quality of battery cell tab electrical connections are presented. In certain embodiments, a first electrical current may be supplied between a first tab group and a second tab group of a battery cell group. A first voltage drop may be measured between the first tab group and the second tab group and a measured cell group resistance may be determined based on the measured first voltage drop. The measured cell group resistance may be compared with a reference cell group resistance to determine a quality of an associated battery cell tab electrical connection.

### TECHNICAL FIELD

This disclosure relates to systems and methods for testing battery tab connection quality. More specifically, but not exclusively, the systems and methods disclosed herein relate to determining a quality of a welded battery tab connection associated with a plurality of battery cells.

### BACKGROUND

Passenger vehicles often include electric batteries for operating features of a vehicle's electrical and drivetrain systems. For example, vehicles commonly include a 12V lead-acid automotive battery configured to supply electric energy to vehicle starter systems (e.g., a starter motor), lighting systems, and/or ignition systems. In electric, fuel cell (“FC”), and/or hybrid vehicles, a high voltage (“HV”) battery system (e.g., a 360V battery system) may be used to power electric drivetrain components of the vehicle (e.g., electric drive motors and the like). For example, an HV rechargeable energy storage system (“ESS”) included in a vehicle may be used to power electric drivetrain components of the vehicle.

A battery system included in a vehicle may comprise a plurality of individual constituent battery cells arranged in a variety of suitable configurations (e.g., battery cells arranged in a stack). In certain configurations, a plurality of individual battery cells in a battery system may be electrically connected via one or more welded tabs. During manufacture and/or assembly of a battery system, however, certain welded tab electrical connections may be improperly formed, thereby detrimentally affecting battery performance. Conventional battery cell tab connection testing may utilize visual, physical, and/or otherwise mechanical testing and/or inspection to determine tab connection quality. Such conventional testing methods, however, may be relatively time consuming and/or costly.

### SUMMARY

Systems and methods disclosed herein may be utilized in connection with determining the quality of battery cell tab electrical connections. Particularly, systems and methods disclosed herein may be utilized in connection with determining the quality of welded battery cell tab electrical connections, although other types of electrical connections may also be tested using the disclosed embodiments.

In some embodiments, a method for testing a welded battery tab connection may include supplying a first electrical current between a first tab group and a second tab group associated with a plurality of battery cells of a battery cell group. A first voltage drop may be measured between the first tab group and the second tab group and a measured cell group resistance may be determined based on the measured first voltage drop. In some embodiments, the measured cell group resistance may be further determined based on an open circuit voltage of the cell group and the first electrical current.

The measured cell group resistance may be compared with a reference cell group resistance to determine a quality of an associated battery cell tab electrical connection and a result of the determination may be output to an associated system or an interface (e.g., in connection with adjusting a system parameter of a manufacturing system associated with forming the tab connection based on the result of the comparison). In some embodiments, the reference cell group resistance may be determined based on an internal resistance of the plurality of battery cells of the cell group and a number of cells of the plurality of battery cells.

In certain embodiments, the result of the quality determination may comprise a first acceptable connection indication if the measured cell group resistance differs from the reference cell group resistance by no more than a threshold amount and a first unacceptable connection indication if the measured cell group resistance differs from the reference cell group resistance by more than the threshold amount. In some embodiments, the threshold amount may be associated with a measured cell group resistance associated with a condition where at least one tab of the plurality of first tabs or the plurality of second tabs is not properly connected.

In further embodiments, the method may further include supplying a second electrical current between the first tab group and an associated common bus and measuring a second voltage drop between the first tab group and the associated common bus. A connection resistance may be determined based on the second voltage drop and the second electrical current, and a quality of the electrical connection between the first tab group and the common bus may be determined based on the connection resistance.

In yet further embodiments, a method of determining a quality of a battery cell tab connection may include connecting a first common bus to a first tab group comprising a first plurality of tabs of a plurality of battery cells of a cell group and connecting a second common bus to a second tab group comprising a second plurality of tabs of the plurality of battery cells of the cell group. An electrical current may be supplied between the first common bus and the second common bus and an electrical current may be measured between the first common bus and the second common bus. A first voltage drop may be measured across the cell group (e.g., between the first tab group and the second tab group and/or between the first common bus and the second common bus), a second voltage drop may be measured between the first tab group and the first common bus, and a third voltage drop may be measured between the second tab group and the second common bus. In some embodiments, the first voltage drop, the second voltage drop, and the third voltage drop may be measured substantially simultaneously.

A first connection resistance of a first connection between the first tab group and the first common bus may be determined based, at least in part, on the second voltage drop and the electrical current. A second connection resistance of a second connection between the second tab group and the second common bus may be determined based, at least in part, on the third voltage drop and the electrical current. A third measured cell group resistance may be based, at least in part, on a first voltage drop and the electrical current.

In certain embodiments, embodiments of the aforementioned methods may be performed by a battery tab connection testing control system and/or implemented using a non-transitory computer-readable medium storing associated executable instructions.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates an isometric view of a portion of a multi-cell battery assembly consistent with embodiments disclosed herein.

FIG. 2 illustrates a cross sectional view of a portion of a multi-cell battery assembly consistent with embodiments disclosed herein.

FIG. 3 illustrates a flow chart of an exemplary method for determining the quality of a cell tab electrical connection of a battery assembly consistent with embodiments disclosed herein.

FIG. 4 illustrates a view of a portion of a mechanical testing head in an open configuration for use in connection with the disclosed systems and methods consistent with embodiments disclosed herein.

FIG. 5 illustrates a view of a portion of a mechanical testing head in a closed configuration for use in connection with the disclosed systems and methods consistent with embodiments disclosed herein.

FIG. 6 illustrates an exemplary system for implementing certain embodiments of the systems and methods disclosed herein.

### DETAILED DESCRIPTION

A detailed description of systems and methods consistent with embodiments of the present disclosure is provided below. While several embodiments are described, it should be understood that the disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

The embodiments of the disclosure will be best understood by reference to the drawings, wherein like parts may be designated by like numerals. The components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor need the steps be executed only once, unless otherwise specified.

Consistent with embodiments disclosed herein, a battery system, such as a battery system included in a vehicle, may comprise a plurality of individual constituent battery cells (e.g., 3-battery cells or the like). The battery system and/or constituent cells may be configured to provide an amount of electric power sufficient to operate a variety of systems associated with a vehicle including, for example, vehicle drivetrain systems. The battery cells may utilize any suitable battery technology or combination thereof. Suitable battery technologies may include, for example, lead-acid, nickel-metal hydride (“NiMH”), lithium-ion (“Li-Ion”), Li-Ion polymer, lithium-air, nickel-cadmium (“NiCad”), valve-regulated lead-acid (“VRLA”) including absorbed glass mat (“AGM”), nickel-zinc (“NiZn”), molten salt (e.g., a ZEBRA battery), nickel manganese cobalt (“NMC”), lithium iron phosphate (“LFP”), lithium manganese oxide (“LMO”), and/or other suitable battery technologies and/or combinations thereof.

Individual battery cells may be electrically connected to form a battery cell group. In certain embodiments, a plurality of battery cell groups may be incorporated in a battery module. A plurality of battery modules may be similarly included in one or more battery packs of a battery system.

In certain embodiments, individual battery cells included in a battery system may comprise prismatic pouch battery cells. Individual battery cells may be arranged in a stack configuration, and may comprise tabs forming battery cell terminals that may be suitably electrically connected for provision of electrical power to loads and/or for charging and/or discharging of the battery cells. In some embodiments, a plurality of individual battery cells (e.g., three cells) may be electrically connected in parallel via associated tabs to form a battery cell group. A plurality of battery cell groups may be electrically connected in series via one or more common buses (e.g., U-channels) to form a battery module included in a battery pack.

In certain embodiments, battery cell tabs and/or an associated common buses may be electrically connected via one or more welds, solder connections, mechanical connectors, and/or electrically conductive adhesives. For example, battery cell tabs and/or associated common busses may be electrically connected via one or more ultrasonic welds, laser welds, ion-beam welds, resistance welds, friction welds, and/or the like. In other embodiments, battery cell tabs and/or associated common busses may be electrically connected via conductive rivets, clips, clamps, and/or the like.

In certain circumstances, during manufacture and/or assembly of a battery system, certain electrical connections between battery cell tabs of a battery cell group and an associated common bus may be improperly formed. For example, in a multi-cell battery assembly including a cell group comprising three individual battery cells, only tabs associated with two cells may be properly electrically coupled to an associated common bus, thereby reducing the total current output of the multi-cell battery assembly. In this manner, improperly formed electrical connections between battery cell tabs and/or associated common busses may detrimentally affect battery performance.

Systems and methods consistent with embodiments disclosed herein may be used in connection with determining a quality of electrical connections between battery cell tabs and/or associated common busses. In some embodiments, the disclosed systems and methods may further be used in connection with identifying improperly formed, acceptable, and/or unacceptable electrical connections between battery cell tabs and/or associated common busses. In certain embodiments, a quality of a welded battery cell tab electrical connection may be determined based on a supplied current and a measured resistance across the electrical connection. In further embodiments, a quality of a welded battery cell tab electrical connection may be determined based on measuring a voltage drop across a cell group of a multi-cell battery assembly, thereby providing an indication of whether a desired number of battery cells in the cell group are electrically connected via the welded battery cell tab electrical connection.

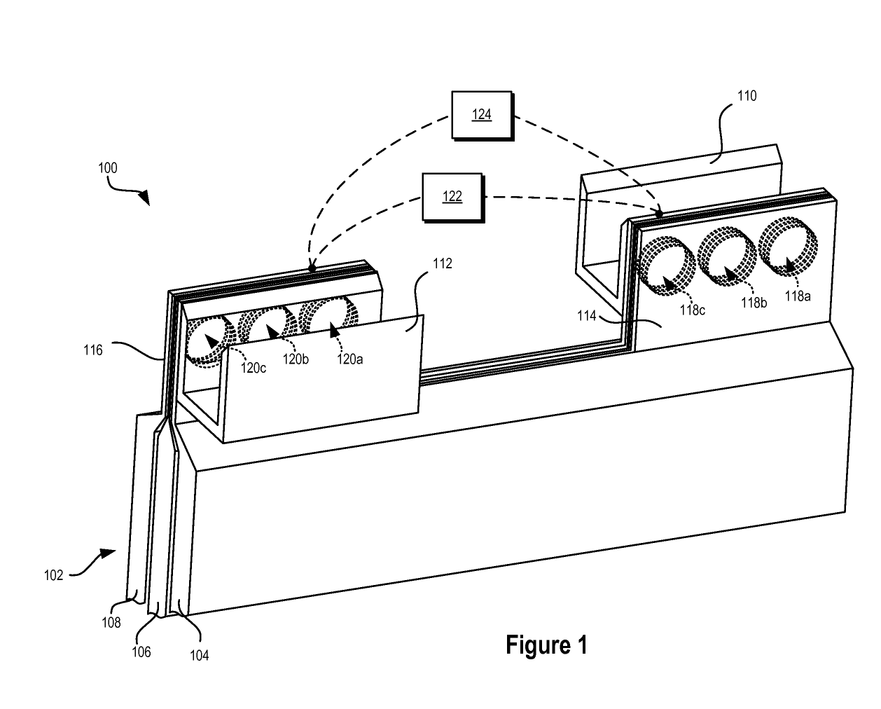

FIG. 1 illustrates an isometric view of a portion of a multi-cell battery assembly 100 consistent with embodiments disclosed herein. In certain embodiments, the multi-cell battery assembly 100 may be included in a battery system configured to power systems associated with a vehicle (not shown). The multi-cell battery assembly 100 may comprise a cell group 102 including a plurality of cells 104-108. The battery cells 104-108 may utilize any suitable battery technology or combination thereof, including any of the battery technologies and/or chemistries disclosed herein. In certain embodiments, the battery cells 104-108 may comprise prismatic pouch battery cells. Although illustrated as comprising three battery cells 104-108, it will be appreciated that any suitable number of battery cells may be included in a cell group 102 of a multi-cell battery assembly 100 consistent with embodiments disclosed herein.

In certain embodiments, cells 104-108 of the cell group 102 may be electrically coupled to common buses 110, 112 via tab groups 114, 116 respectively. In some embodiments, the common busses 110, 112 may be referred to as U-channels. The common busses 110, 112 may comprise any suitable electrically conductive material including, without limitation, copper, aluminum, and/or the like. The common busses 110, 112 may be configured to electrically connect cell group 102 in series with adjacent cell groups (not shown) included in the battery system.

Each tab group 114, 116 may comprise a plurality of individual cell tabs, each individual cell tab of the plurality of cell tabs being associated with an individual cell of the plurality of cells 104-108. For example, tab group 114 may comprise a first tab associated with cell 104, a second tab associated with cell 106, and a third tab associated with cell 108. In certain embodiments, individual cell tabs included in the tab groups 114, 116 may comprise terminals of cells 104-108 associated respectively therewith. For example, individual cell tabs included in tab group 114 may comprise first terminals of cells 104-108 and individual tabs included in tab group 116 may comprise second terminals of cells 104-108.

Tab groups 114, 116 may be respectively electrically connected to the common busses 110, 112 using any suitable electrical connection. For example, tab groups 114, 116 may be respectively electrically connected to common busses 110, 112 via one or more weld connections 118a-118c and 120a-120c, solder connections, mechanical connections, and/or electrically conductive adhesive connections, and/or any other type of electrical connections disclosed herein. For illustrative purposes, embodiments of the disclosed systems and methods are discussed herein in connection with welded electrical connections, although it will be appreciated that the disclosed embodiments may be further used in connection with any other type of electrical connection.

In certain embodiments, cell tabs associated with tab groups 114, 116 may first be connected together using a first suitable electrical connection operation and subsequently connected to common busses 110, 112 respectively using a second suitable electrical connection operation. In other embodiments, cell tabs associated with tab groups 114, 116 may be electrically connected to the common busses 110, 112 respectively in a single suitable electrical connection operation (e.g., via a single ultrasonic welding operation or the like).

In certain embodiments, weld connections 118a-118c and 120a-120c may comprise one or more weld nuggets. Although described in certain instances herein as separately-identifiable components, the weld-nuggets may generally be considered as zones of coalescence between adjacent cell tabs associated with tab groups 114, 116.

As discussed above, certain electrical connections between tab groups 114, 116 and common busses 110, 112 may be improperly formed during manufacture and/or assembly of the battery system. For example, an improperly formed weld may only properly electrically connect cell tabs associated with cells 106 and 108 to common bus 110, whereas a cell tab associated with cell 104 may not be electrically connected and/or not be well connected to common bus 110. Such improperly formed electrical connections between tab groups 114, 116 and common busses 110, 112 may detrimentally affect battery performance.

Consistent with embodiments disclosed herein, a quality of an electrical connection between tab groups 114, 116 and associated common busses 110, 112 may be determined, at least in part, by measuring a voltage drop across a cell group 102 associated with a current supplied through the constituent cells 104-108 of cell group 102. In certain embodiments, the current may be supplied by a current source 122. In certain embodiments, the current source 122 may comprise a voltage source and a precision resistor, thereby allowing a precise current to be supplied through the cells 104-108 of cell group 102. The voltage drop across the cell group 102 may be measured by a voltmeter 124 configured to measure a voltage across cell group 102 (e.g., a voltage measured across tab groups 114, 116).

Voltage drop across the cell group 102 may be expressed according to the following:

V_{drop}=E−IₛᵤₚₚR_{group} Eq. 1

where V_{drop} comprises the voltage drop across the cell group, Iₛᵤₚₚ comprises a supplied current through the cell group, E comprises the Electromotive force and/or open circuit voltage of the cells 104-108 of cell group 102, and R_{group} comprises an internal resistance of the cell group 102. Using Equation 1 and a measured voltage drop across the cell group 102, V_{drop}_{_{—}}ₘₑₐₛ, a measured internal resistance of the cell group 102, R_{group}_{_{—}}ₘₑₐₛ, may be determined according to the following:

$${R}_{group \_ meas} = \frac{( E - {V}_{drop \_ meas} )}{{I}_{supp}} \qquad Eq . 2$$

A reference internal resistance of cell group 102, R_{ref}, associated with a condition wherein electrical connection between tab groups 114, 116 are properly formed and/or of acceptable quality may be expressed according to the following:

$${R}_{ref} = \frac{{R}_{cell}}{n} \qquad Eq . 3$$

where R_{cell} comprises a known internal resistance of individual cells 104-108 (e.g., a known measured and/or approximated internal resistance of the cells) and n comprises a number of cells included in the cell group 102.

To determine a quality of an electrical connection and/or whether an electrical connection has been properly formed between individual tabs associated with tab groups 114, 116 and/or the common buses 110, 112, a measured internal resistance of the cell group 102, R_{group}_{_{—}}ₘₑₐₛ, determined using Equation 2, may be compared with the reference internal resistance of cell group 102, R_{ref}, determined using Equation 3. If the measured internal resistance differs from the reference internal resistance by a certain tolerance threshold, it may be determined that an electrical connection associated with tab groups 114, 116 and/or common buses 110, 112 is not of acceptable quality and/or has not been properly formed. In certain embodiments, the threshold may be determined based on characterized and/or otherwise measured information relating sheer and/or pull strength of an electrical connection with electrical resistance of the electronic connection (e.g., weld sheer and/or pull strength vs. weld electrical resistance or the like).

As an example, in a cell group 102 comprising three cells 104-108, if a measured internal resistance is approximately 50% larger than a reference internal resistance for the cell group 102, it may be determined that the electrical connections associated with the cell group 102 are not of acceptable quality and/or have not been properly formed. For example, in such a circumstance, it may be determined that only two of the cells of cell group 102 are associated with properly formed electrical connections (e.g., connections to common buses 110,112). Based on such a determination, departures from manufacturing tolerances associated with the multi-cell battery assembly may be identified and remedied.

It will be appreciated that a number of variations can be made to the embodiments of the disclosed multi-cell battery assembly 100 presented in connection with FIG. 1 within the scope of the inventive body of work. For example, any suitable number of constituent cells may be included in a multi-cell battery assembly 100 consistent with embodiments disclosed herein. Moreover, a multi-cell battery assembly 100 and/or its constituent components may be configured in a variety of other geometries. Thus it will be appreciated that FIG. 1 is provided for purposes of illustration and explanation and not limitation.

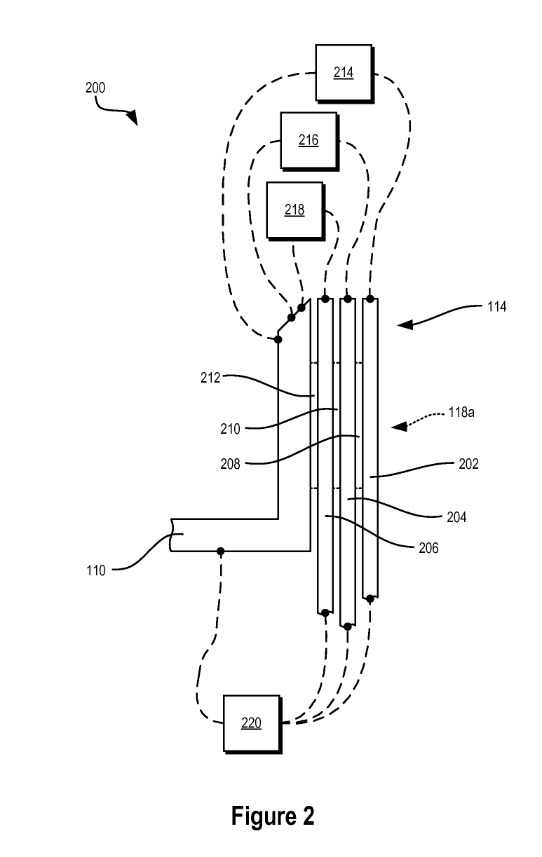

FIG. 2 illustrates a cross sectional view of a portion of a multi-cell battery assembly 200 consistent with embodiments disclosed herein. Particularly, FIG. 2 illustrates a cross section view of the tab group 114 and associated common bus 110 illustrated and described above in connection with FIG. 1. As illustrated in FIG. 2, a weld connection 118a electrically connecting a plurality of tabs 202-206 associated with tab group 114 and/or common bus 110 may comprise a plurality of weld nuggets 208-212. For example, as illustrated, a first weld nugget 208 may electrically connect a first tab 202 with a second tab 204, a second weld nugget 210 may electrically connect the second tab 204 with a third tab 206, and a third weld nugget 212 may electrically connect the third tab 206 with the common bus 110.

In certain embodiments, a quality of a welded battery cell tab electrical connection may be determined based on a supplied current and a measured resistance across the electrical connection. In some embodiments, such a determination may be performed based using, at least in part, one or more voltmeters 214-218 and one or more current sources 220 associated with and/or included in a testing control system (not shown).

In certain embodiments, the common bus 110 may have a first end and a second end disposed on opposing sides of a weld connection 118a. Similarly, cell tabs 202-206 may have first ends and second ends disposed on opposing sides of the weld connection 118a. The first end of the common bus 110 and the first ends of cell tabs 202-206 may be disposed on opposing sides of the weld connection 118a.

Cell tabs 202-206 may be electrically connected to one or more current sources 220, which may be configured to supply a current between the first end of the common bus 110 and the first ends of the cell tabs 202-206 (e.g., via wires, conductors, and/or a suitable testing head apparatus). In certain embodiments, the current source 220 may comprise a voltage source and a precision resistor.

As an example, the current source 220 may be configured to supply current between a first end of the common bus 110 and the first end of cell tab 206. For current supplied by current source 220 to move between the first end of the common bus and the first end of the cell tab 202, the current moves through weld nugget 212. A voltmeter 218 may measure a voltage differential between a second end of the common bus 110 and a second end of cell tab 206.

From the supplied current and the measured voltage, the resistance of weld nugget 212 may be calculated. The calculated resistance may be indicative of the quality of the weld nugget 212. For example, if the weld nugget 212 does not include continuous coalescence between the cell tab 206 and the common bus 110, flow of current form the cell tab 206 to the common bus 110 may be impeded, thereby causing the calculated resistance to increase. Similarly, if the weld nugget 212 is broken and/or has significant cracking, the calculated resistance may also increase. In another example, the current source 220 may be connected to the first ends of the cell tabs 202-206. A first current, I₁, may be supplied by the current source 220 between the first end of the common bus 110 and the first end of cell tab 202, a second current, I₂, may be supplied by the current source 220 between the first end of the common bus 110 and the first end of cell tab 204, and a third current, I₃, may be supplied by the current source 220 between the first end of the common bus 110 and the first end of cell tab 206. In certain embodiments, the first current, second current, and third current may be substantially similar, such that each is approximately one-third of a total stack current I. A first voltmeter 214 may measure a first voltage, V₁, between a second end of the common bus 110 and a second end of cell tab 202, a second voltmeter 216 may measure a second voltage, V₂, between a second end of the common bus 110 and a second end of cell tab 204, and a third voltmeter 218 may measure a third voltage, V₃, between a second end of the common bus 110 and a second end of cell tab 206. Based on the total stack current I and the measured voltages, V₁₋₃, a resistance of each weld nugget 208-212 may be determined. A first nugget resistance, R₁₂, between cell tab 202 and cell tab 204 may be associated with weld nugget 208. A second nugget resistance, R₂₃, between cell tab 204 and cell tab 206 may be associated with weld nugget 210. A third nugget resistance, R_{3b}, between cell tab 206 and common bus 110 may be associated with weld nugget 212. The first, second, and third nugget resistances may be determined or calculated as three unknowns in the following equations:

$$\begin{matrix}{V}_{1} = I ( \frac{{R}_{12}}{3} + \frac{2 {R}_{23}}{3} + {R}_{3 b} ) & Eq . 4 \\ {V}_{2} = I ( \frac{2 {R}_{23}}{3} + {R}_{3 b} ) & Eq . 5 \\ {V}_{3} = I ( {R}_{3 b} ) & Eq . 6\end{matrix}$$

In certain embodiments, the individual resistances of each of the weld nuggets 208-212 may be compared to a weld quality range having a predetermined minimum nugget resistance and a predetermined maximum nugget resistance. The result of the comparison may then be output, for example, to a computer logging data, and operator testing the battery and/or portions thereof, an automated testing and/or sorting process and/or the like. In certain embodiments, the specific resistance values associated with the weld quality range may depend, among other things, on a type of welding process used to create the weld nuggets 208-212 and/or weld connection 118a. Results of the comparisons may comprise, without limitation, a measurement error, an indication of electrical connection quality, an indication of an acceptable electrical connection, and/or an indication of an unacceptable electrical connection. In certain embodiments, a measurement error may be output if a determined resistance is below a predetermined minimum nugget resistance (e.g., a resistance associated with a solid and/or unwelded conductive material). In further embodiments, an unacceptable connection may be indicated if a determined resistance is above the predetermined maximum nugget resistance, thereby indicating an associated electrical connection quality is low as current is experiencing resistance flowing through the connection. An acceptable connection may be indicated if a determined resistance is between the predetermined minimum and maximum nugget resistances. The parenthetical quantities of Equations 4-6 may be associated with resistance constants of portions of weld connection 118a, and may be used to determine a total weld resistance, Rₜₒₜₐₗ, of the weld connection 118a. The total weld resistance may be indicative of the total quality of the weld connection 118a as a whole. In certain embodiments, the total weld resistance may be expressed as the total effective resistance between cell tab 202 and common bus 110 according to the following

$${R}_{total} = \frac{{V}_{1}}{I} \qquad Eq . 6$$

In some embodiments, a weld quality range may be compared with a total determined weld resistance to determine total weld quality. For example, to determine whether a weld connection is acceptable, a determination may be made whether the total determined weld resistance is between a predetermined minimum total weld resistance and a predetermined maximum total weld resistance. If the total determined weld resistance is between the predetermined minimum and maximum, the weld connection may be determined to be acceptable. If the total determined weld resistance with resistance exceeds the predetermined maximum, the weld connection may be determined to be unacceptable. If the total determined weld resistance is below the predetermined minimum, a measurement error may be identified.

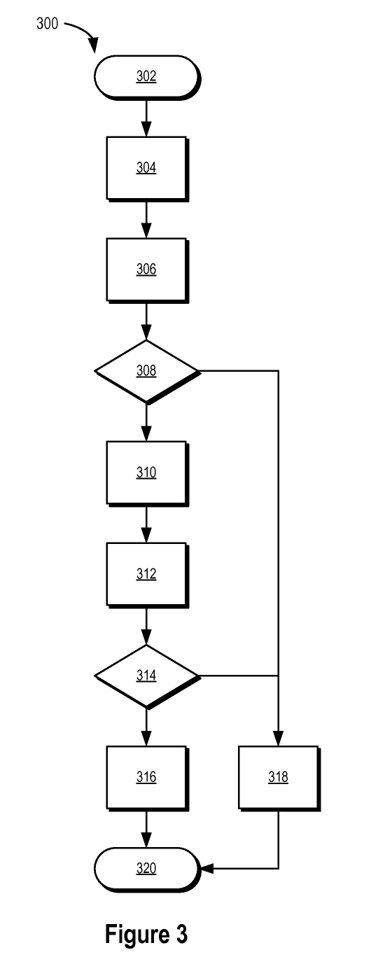

FIG. 3 illustrates a flow chart of an exemplary method 300 for determining the quality of a battery cell tab electrical connection of a battery assembly consistent with embodiments disclosed herein. In certain embodiments, the exemplary method 300 may be performed by a testing control system configured to, among other things, control and/or supply one or more electrical currents, perform one or more measurements (e.g., voltage measurements), perform certain calculations based on the measurements, determine the quality of an electrical connection based on the same, and/or perform any other aspects of the systems and methods disclosed herein.

At 302, the method 300 may initiate. At 304, a current may be supplied across a cell group of a multi-cell battery assembly. In certain embodiments, the current may be supplied via one or more tab groups associated with the cell group. At 306, a voltage drop may be measured across the cell group in response to the supplied current.

A determination may be made at 308 as to whether a measured internal resistance of the cell group calculated based on the measured voltage drop differs from a reference internal resistance by a certain tolerance threshold amount. In certain embodiments, if the measured internal resistance differs from the reference internal resistance by more than the threshold amount, it may be determined that an electrical connection associated with the cell group is not of acceptable quality and/or has not been properly formed. In such a circumstance, the method 300 may proceed to 318, where an indication may be provided to a user and/or another system of an unacceptable electrical connection. In other embodiments, a manufacturing process may be adjusted based on the determination (e.g., a process associated with creation and/or formation of the electrical connection). For example, in some embodiments, a process tool used to form the electrical connection as part of the manufacturing process may be realigned, have certain processing parameters adjusted, and/or be prevented from forming additional electrical connections until serviced.

If the measured internal resistance does not differ from the reference internal resistance by more than the threshold amount, the method 300 may proceed to 310. In certain embodiments, such a determination may indicate that a proper number of individual cells in a cell group have been electrically connected. At 310, a current may be supplied across a tab group of the cell group and/or an associated common bus. At 312, a voltage may be measured across the tab group and/or associated common bus.

A determination may be made at 314 as to whether a measured resistance across the tab group and/or associated common bus determined based on the measured voltage is within a certain range. In some embodiments, the range may be defined by a predetermined minimum resistance and a predetermined maximum resistance. If the measured resistance across the tab group and/or associated common bus is within the range, the method 300 may proceed to 316, where an indication may be provided to a user and/or another system of an acceptable electrical connection. If the measured resistance across the tab group and/or associated common bus exceeds the range, the method 300 may proceed to 318, where an indication may be provided to a user and/or another system of an unacceptable electrical connection. In further embodiments, a manufacturing process may be adjusted based on such a determination. For example, in some embodiments, a process tool used to form the electrical connection as part of the manufacturing process may be realigned, have certain processing parameters adjusted, and/or be prevented from forming additional electrical connections until serviced.

In other embodiments, if the measured resistance across the tab group and/or associated common bus is less than the predetermined minimum resistance, the method 300 may further comprise providing an indication to a user and/or another system of a testing and/or measurement error. The method 300 may proceed to terminate at 320.

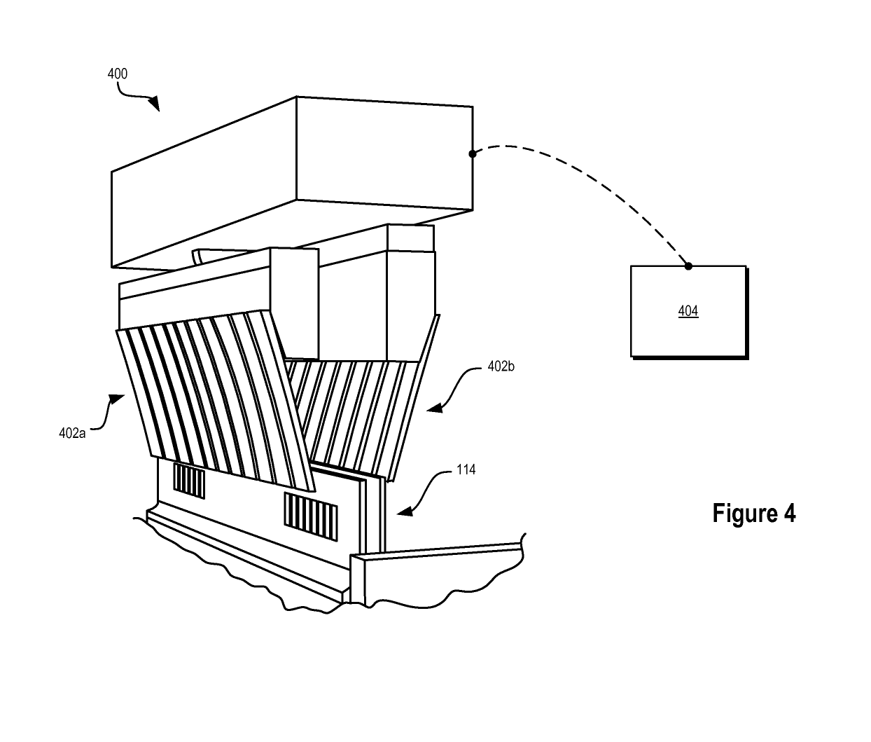

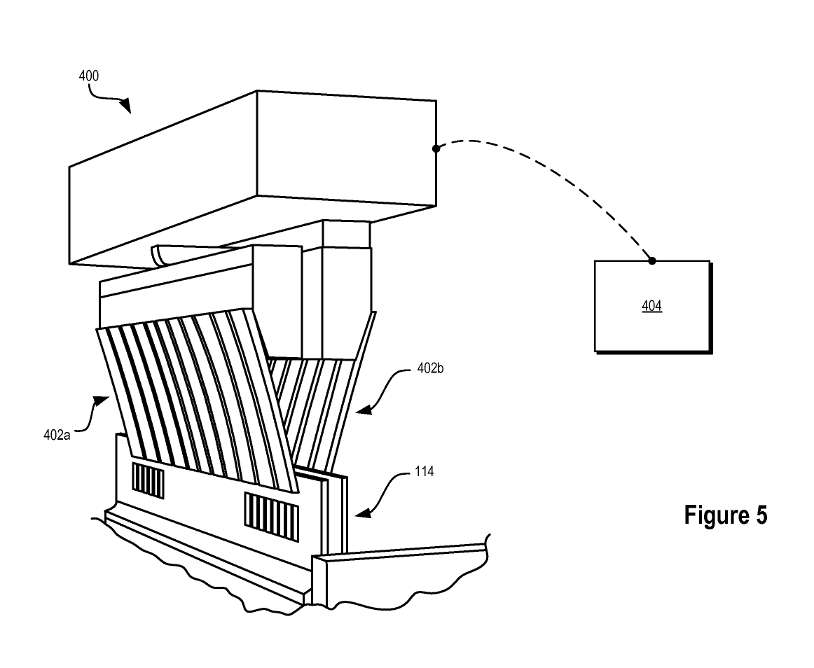

FIG. 4 illustrates a view of a portion of a mechanical testing head 400 in an open configuration for use in connection with the disclosed systems and methods consistent with embodiments disclosed herein. FIG. 5 illustrates a view of a portion of the mechanical testing head 400 in a closed configuration for use in connection with the disclosed systems and methods consistent with embodiments disclosed herein.

The mechanical testing head 400 may be in communication with a testing control system 404 configured to, at least in part, control the operation of the mechanical testing head 400 and/or perform one or more determinations of electrical connection quality consistent with embodiments disclosed herein. Among other things, the testing control system 404 may comprise one or more voltmeters and/or current sources configured to be used in connection with determining electrical connection quality consistent with embodiments disclosed herein.

In some embodiments, the testing head 400 may comprise one or more combs 402a, 402b configured to electrically contact opposing sides of a tab group 114 during testing and/or measurement operations when the testing head is in a closed configuration (e.g., as illustrated in connection with FIG. 5). For example, in certain embodiments, the one or more combs 402a, 402b may be configured to provide contact points for supplying an electrical current across the tab group 114 and/or across a cell group associated with the tab group 114. In further embodiments, the one more combs 402a, 402b may be configured to provide contact points for measuring one more voltages across the tab group and/or across a cell group associated with the tab group 114.

In certain embodiments, as the mechanical testing head 400 is positioned relative to one or more tab group 114 and/or associated common busses (not shown), the combs 402a, 402b may close in a horizontal direction to electrically contact opposing sides of the tab group 114 and/or associated common bus assembly, as illustrated in FIG. 5. In some embodiments, this operation may be achieved by a two-stage bidirectional linkage system configured to convert a vertical motion into vertical and horizontal action. For example, as the testing head 400 is lowered relative to the tab group 114, the combs 402a, 402b may close horizontally so as to make electrical contact with opposing sides of the tab group 114 and/or an associated common bus assembly. In certain embodiments, such an operation may improve alignment of the testing head 400 relative to the tab group 114 and/or facilitate a certain degree of misalignment without significantly affecting testing head 400 performance.

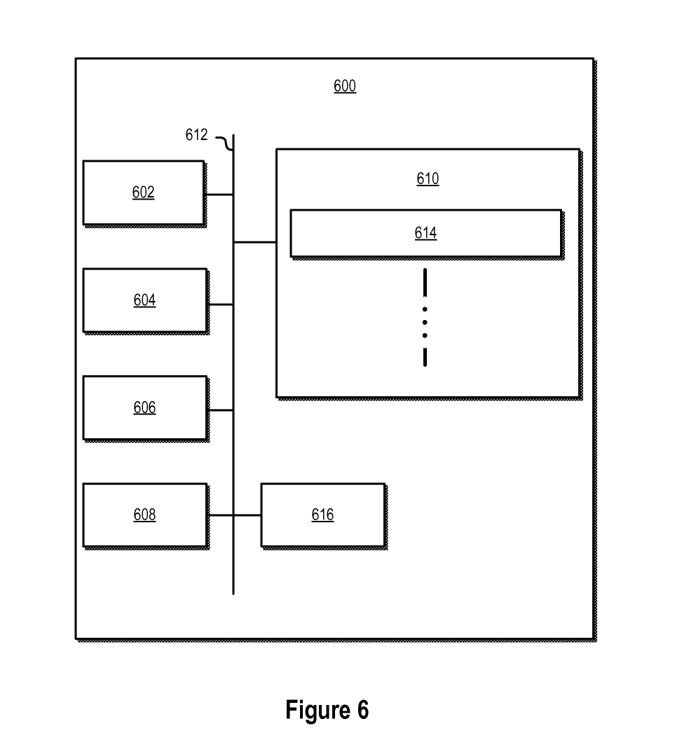

FIG. 6 illustrates an exemplary system 600 for implementing certain embodiments of the systems and methods disclosed herein. In certain embodiments, the computer system 600 may be a personal computer system, a server computer system, a testing control system, and/or any other type of system suitable for implementing the disclosed systems and methods. In further embodiments, the computer system 600 may be any portable electronic computer system or electronic device including, for example, a notebook computer, a smartphone, and/or a tablet computer.

As illustrated, the computer system 600 may include, among other things, one or more processors 602, random access memory (“RAM”) 604, a communications interface 606, a user interface 608, a measurement and/or testing interface 616 configured to supply one or more electrical currents and/or measure one or more voltages, and a non-transitory computer-readable storage medium 610. The processor 602, RAM 604, communications interface 606, user interface 608, measurement and/or testing interface 616, and computer-readable storage medium 610 may be communicatively coupled to each other via a common data bus 612. In some embodiments, the various components of the computer system 600 may be implemented using hardware, software, firmware, and/or any combination thereof.

User interface 608 may include any number of devices allowing a user to interact with the computer system 600. For example, user interface 608 may be used to display an interactive interface to a user. The user interface 608 may be a separate interface system communicatively coupled with the computer system 600 or, alternatively, may be an integrated system such as a display interface for a laptop or other similar device. In certain embodiments, the user interface 608 may be produced on a touch screen display. The user interface 608 may also include any number of other input devices including, for example, keyboard, trackball, and/or pointer devices.

The communications interface 606 may be any interface capable of communicating with other computer systems, peripheral devices, and/or other equipment communicatively coupled to computer system 600. For example, the communications interface 606 may allow the computer system 600 to communicate with other computer systems (e.g., computer systems associated with external databases and/or the Internet), allowing for the transfer as well as reception of data from such systems. The communications interface 606 may include, among other things, a modem, a satellite data transmission system, an Ethernet card, and/or any other suitable device that enables the computer system 600 to connect to databases and networks, such as LANs, MANs, WANs and the Internet.

Processor 602 may include one or more general purpose processors, application specific processors, programmable microprocessors, microcontrollers, digital signal processors, FPGAs, other customizable or programmable processing devices, and/or any other devices or arrangement of devices that are capable of implementing the systems and methods disclosed herein.

Processor 602 may be configured to execute computer-readable instructions stored on non-transitory computer-readable storage medium 610. Computer-readable storage medium 610 may store other data or information as desired. In some embodiments, the computer-readable instructions may include computer executable functional modules 614. For example, the computer-readable instructions may include one or more functional modules configured to implement all or part of the functionality of the systems and methods described above. Specific functional models that may be stored on computer-readable storage medium 610 may include a module configured to control a current source, a module configured to measure one or more voltages, a module configured to determine one or more measured resistances, a module configured to perform electrical connection quality determinations consistent with embodiments disclosed herein, and/or any other module or modules configured to implement the systems and methods disclosed herein.

The system and methods described herein may be implemented independent of the programming language used to create the computer-readable instructions and/or any operating system operating on the computer system 600. For example, the computer-readable instructions may be written in any suitable programming language, examples of which include, but are not limited to, C, C++, Visual C++, and/or Visual Basic, Java, Perl, or any other suitable programming language. Further, the computer-readable instructions and/or functional modules may be in the form of a collection of separate programs or modules, and/or a program module within a larger program or a portion of a program module. The processing of data by computer system 600 may be in response to user commands, results of previous processing, or a request made by another processing machine. It will be appreciated that computer system 600 may utilize any suitable operating system including, for example, Unix, DOS, Android, Symbian, Windows, iOS, OSX, Linux, and/or the like.

Although the foregoing has been described in some detail for purposes of clarity, it will be apparent that certain changes and modifications may be made without departing from the principles thereof. It is noted that there are many alternative ways of implementing both the processes and systems described herein. Accordingly, the present embodiments are to be considered illustrative and not restrictive, and the invention is not to be limited to the details given herein, but may be modified within the scope and equivalents of the appended claims.

The foregoing specification has been described with reference to various embodiments. However, one of ordinary skill in the art will appreciate that various modifications and changes can be made without departing from the scope of the present disclosure. For example, various operational steps, as well as components for carrying out operational steps, may be implemented in alternate ways depending upon the particular application or in consideration of any number of cost functions associated with the operation of the system. Accordingly, any one or more of the steps may be deleted, modified, or combined with other steps. Further, this disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced, are not to be construed as a critical, a required, or an essential feature or element.

As used herein, the terms “comprises” and “includes,” and any other variation thereof, are intended to cover a non-exclusive inclusion, such that a process, a method, an article, or an apparatus that comprises a list of elements does not include only those elements but may include other elements not expressly listed or inherent to such process, method, system, article, or apparatus. Also, as used herein, the terms “coupled,” “coupling,” and any other variation thereof are intended to cover a physical connection, an electrical connection, a magnetic connection, an optical connection, a communicative connection, a functional connection, and/or any other connection.

Those having skill in the art will appreciate that many changes may be made to the details of the above-described embodiments without departing from the underlying principles of the invention. The scope of the present invention should, therefore, be determined only by the following claims.

1. A method of determining a quality of a battery cell tab connection comprising:
supplying a first electrical current between a first tab group and a second tab group, the first tab group comprising a plurality of first tabs of a plurality of battery cells of a cell group, the second tab group comprising a plurality of second tabs of the plurality of battery cells of the cell group;
measuring a first voltage drop between the first tab group and the second tab group
determining a measured cell group resistance based, at least in part, on the measured first voltage drop; and
comparing the measured cell group resistance with a reference cell group resistance; and
outputting a result of the comparison.

2. The method of claim 1, wherein the result comprises:
a first acceptable connection indication if the measured cell group resistance differs from the reference cell group resistance by no more than a threshold amount; and
a first unacceptable connection indication if the measured cell group resistance differs from the reference cell group resistance by more than the threshold amount.

3. The method of claim 2, wherein the threshold amount is associated with a measured cell group resistance associated with a condition where at least one tab of the plurality of first tabs or the plurality of second tabs is not properly connected.

4. The method of claim 1, wherein determining the measured cell group resistance is further based on an open circuit voltage of the cell group and the first electrical current.

5. The method of claim 1, wherein the method further comprises determining the reference cell group resistance.

6. The method of claim 5, wherein the determination of the reference cell group resistance is based on an internal resistance of the plurality of battery cells of the cell group and a number of cells of the plurality of battery cells.

7. The method of claim 1, wherein outputting the result comprises providing an indication of the result to a user via an interface.

8. The method of claim 1, wherein the method further comprises adjusting a system parameter of a manufacturing system associated with forming the tab connection based on the result of the comparison.

9. The method of claim 1, wherein the battery cell tab connection comprises a weld connection.

10. The method of claim 1, wherein the method further comprises:
supplying a second electrical current between the first tab group and an associated common bus;
measuring a second voltage drop between the first tab group and the associated common bus;
determining a connection resistance based on the second voltage drop and the second electrical current; and
determining a quality of an electrical connection between the first tab group and the common bus based on the connection resistance.

11. The method of determining a quality of a battery cell tab connection comprising:
connecting a first common bus to a first tab group comprising a first plurality of tabs of a plurality of battery cells of a cell group;
connecting a second common bus to a second tab group comprising a second plurality of tabs of the plurality of battery cells of the cell group;
supplying an electrical current between the first common bus and the second common bus;
measuring the electrical current between the first common bus and the second common bus;
measuring a first voltage drop across the cell group;
measuring a second voltage drop between the first tab group and the first common bus;
measuring a third voltage drop between the second tab group and the second common bus;
determining a first connection resistance of a first connection between the first tab group and the first common bus based, at least in part, on the second voltage drop and the electrical current;
determining a second connection resistance of a second connection between the second tab group and the second common bus based, at least in part, on the third voltage drop and the electrical current; and
determining a measured cell group resistance based, at least in part, on the first voltage drop and the electrical current.

12. The method of claim 11, wherein the electrical current, the first voltage drop, the second voltage drop, and the third voltage drop are measured substantially simultaneously.

13. The method of claim 11, wherein the first voltage drop is measured between the first tab group and the second tab group

14. The method of claim 11, wherein the first voltage drop is measured between the first common bus and the second common bus.

15. A non-transitory computer-readable medium comprising instructions that, when executed by a processor, cause the processor to perform a method for determining a quality of a battery cell tab connection comprising:
supplying a first electrical current between a first tab group and a second tab group, the first tab group comprising a plurality of first tabs of a plurality of battery cells of a cell group, the second tab group comprising a plurality of second tabs of the plurality of battery cells of the cell group;
measuring a first voltage drop between the first tab group and the second tab group
determining a measured cell group resistance based, at least in part, on the measured voltage drop; and
comparing the measured cell group resistance with a reference cell group resistance; and
outputting a result of the comparison.

16. The non-transitory computer-readable medium of claim 15, wherein the result comprises:
a first acceptable connection indication if the measured cell group resistance differs from the reference cell group resistance by no more than a threshold amount; and
a first unacceptable connection indication if the measured cell group resistance differs from the reference cell group resistance by more than the threshold amount.

17. The non-transitory computer-readable medium of claim 16, wherein the threshold amount is associated with a measured cell group resistance associated with a condition where at least one tab of the plurality of first tabs or the plurality of second tabs is not properly connected.

18. The non-transitory computer-readable medium of claim 15, wherein determining the measured cell group resistance is further based on an open circuit voltage of the cell group and the first electrical current.

19. The non-transitory computer-readable medium of claim 15, wherein the method further comprises determining the reference cell group resistance based on an internal resistance of the plurality of battery cells of the cell group and a number of cells of the plurality of battery cells.

20. The non-transitory computer-readable medium of claim 15, wherein the method further comprises:
supplying a second electrical current between the first tab group and an associated common bus;
measuring a second voltage drop between the first tab group and the associated common bus;
determining a connection resistance based on the second voltage drop and the second electrical current; and
determining a quality of an electrical connection between the first tab group and the common bus based on the connection resistance.
